(19) United States
(12) Patent Application Publication
(10) Pub. No.: US 2004/0103351 A1
(43) Pub. Date: May 27, 2004

(54) Redundant data storage in imaging devices

(76) Inventor: B. Mark Hirst, Boise, ID (US)

Correspondence Address: HEWLETT-PACKARD COMPANY, Intellectual Property Administration, P.O. Box 272400, Fort Collins, CO, 80527-2400, US

(21) Appl. No.: 10/303,478

(22) Filed: Nov. 25, 2002

(51) Int. Cl. H04L 1/22; H04B 1/74; H02H 3/05; H05K 10/00; H03K 19/003; G11C 29/00

(52) U.S. Cl. 714/710

(57) ABSTRACT

Redundant data storage systems and methods for imaging devices are disclosed. In one embodiment, a control/memory system for an imaging device comprises at least two separate components each including its own processor and memory, and a data recovery module configured to restore data to memory within the control/memory system in the event such data are lost or corrupted. In one embodiment, a data recovery method comprises comparing data stored on various different memories of the imaging device, determining if there is an inconsistency between the data of the various different imaging device memories, determining which data are correct and which data are incorrect if there is an inconsistency, and causing the incorrect data to be replaced with the correct data.

### FIELD OF THE INVENTION

The present disclosure relates to redundant data storage in imaging devices. More particularly, the disclosure relates to redundantly storing data in multiple memories of an imaging device to preserve data that may otherwise be lost or corrupted.

### BACKGROUND OF THE INVENTION

Electrophotographic printing and copying (i.e., imaging) devices typically include memory in which various data are stored. These data may pertain to information regarding the particular imaging device (e.g., device serial number), machine constants used by the device (e.g., image alignment offsets), device use information (e.g., page counts), and the like. Normally, these data are stored in one or more memory elements contained within the imaging device, for instance, located on one or more internal circuit boards.

Occasionally, these data are lost and/or corrupted during device use or servicing. For example, where power to the imaging device is removed (e.g., during a power failure) while data are being written, the data may be corrupted. In another example, a code virus may similarly corrupt data stored within memory. Data loss can occur, for instance, when a given device component having its own memory element is replaced. In such a situation, the data stored on the memory element of the old component may be lost. Such loss or corruption is, of course, undesirable. First, the loss or corruption of data may interfere with proper device operation and may result in customer frustration. Further, loss or corruption of data may interfere with data collection that the manufacturer may use to better serve the needs of the customer.

Although some of these data may be recoverable, it typically is not efficient to do so. For example, if machine constants data are lost, these data typically can be re-downloaded to the imaging device by referencing a bar code or other indicia adhered to the printer that contains these data. To do this, however, a relatively expensive service call is typically required and use of the imaging device may be interrupted until such time when a technician arrives. Other data cannot be recovered at all. For instance, where use information has been stored in a component that has been replaced, this use information typically will be permanently unavailable.

From the foregoing, it can be appreciated that it would be desirable to have redundant storage capabilities such that data is stored in more than one location. With such capabilities, data lost from and/or corrupted in one location can be effectively and efficiently recovered.

### SUMMARY OF THE INVENTION

The present disclosure relates to redundant data storage in imaging devices. In particular, the disclosure relates to a control/memory system for an imaging device. In one embodiment, the control/memory system comprises at least two separate components each including its own processor and memory, and a data recovery module configured to restore data to memory within the control/memory system in the event such data are lost or corrupted.

The disclosure further relates to a method for recovering data within an imaging device. In one embodiment, the method comprises comparing data stored on various different memories of the imaging device, determining if there is an inconsistency between the data of the various different imaging device memories, determining which data are correct and which data are incorrect if there is an inconsistency, and causing the incorrect data to be replaced with the correct data.

### BRIEF DESCRIPTION OF THE DRAWINGS

The invention can be better understood with reference to the following drawings. The components in the drawings are not necessarily to scale, emphasis instead being placed upon clearly illustrating the principles of the present invention.

FIG. 1 is a schematic side view of an electrophotographic imaging device having redundant data storage capabilities.

FIG. 2 is a block diagram of an example control/memory system of the imaging device of FIG. 1.

FIG. 3 is a block diagram of an example configuration for an imaging device controller shown in FIG. 2.

FIG. 4 is a flow diagram of an example method for providing redundant data storage in an imaging device.

FIG. 5 is a flow diagram of an example of operation of a data recovery module shown in FIG. 3.

### DETAILED DESCRIPTION

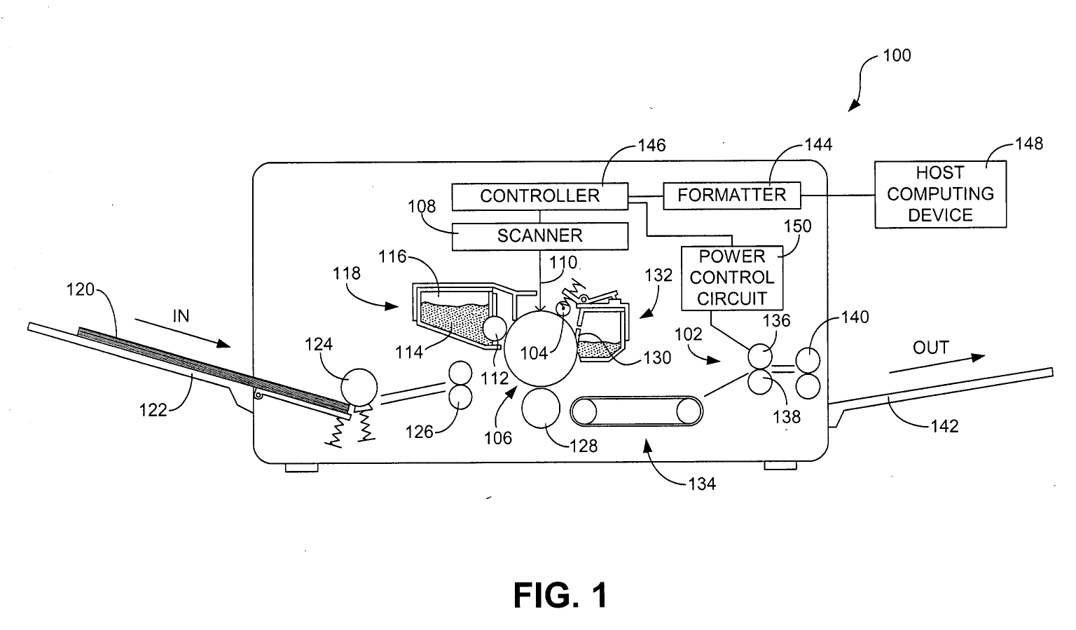

Referring now in more detail to the drawings, in which like numerals indicate corresponding parts throughout the several views, FIG. 1 illustrates a schematic side view of an electrophotographic imaging device 100. By way of example, the device 100 comprises a laser printer. It is to be understood, however, that the device 100 can, alternatively, comprise any other such imaging device including, for instance, a photocopier or a facsimile machine. Moreover, although the imaging device 100 is shown and described as a laser-based device for purposes of example, persons having ordinary skill in the art will appreciate that the present disclosure is also applicable to other imaging devices, for instance ink-based devices.

As indicated in FIG. 1, the device 100 comprises a print engine that includes a charge member or roller 104 that is used to charge the surface of a photoconductor member or drum 106 to a predetermined voltage. A laser diode (not shown) is provided within a laser scanner 108 that emits a laser beam 110 which is pulsed on and off as it is swept across the surface of the photoconductor drum 106 to selectively discharge the surface of the photoconductor drum. In the orientation shown in FIG. 1, the photoconductor drum 106 rotates in the counterclockwise direction. A developing roller 112 is used to develop a latent electrostatic image residing on the surface of photoconductor drum 106 after the surface voltage of the photoconductor drum has been selectively discharged. Toner 114 is stored in a toner reservoir 116 of an electrophotographic print cartridge 118. The developing roller 112 includes an internal magnet (not shown) that magnetically attracts the toner 114 from the print cartridge 118 to the surface of the developing roller. As the developing roller 112 rotates (clockwise in FIG. 1), the toner 114 is attracted to the surface of the developing roller 112 and is then transferred across the gap between the surface of the photoconductor drum 106 and the surface of the developing roller to develop the latent electrostatic image.

Recording media 120, for instance sheets of paper, are loaded from an input tray 122 by a pickup roller 124 into a conveyance path of the device 100. Each recording medium 120 is individually drawn through the device 100 along the conveyance path by drive rollers 126 such that the leading edge of each recording medium is synchronized with the rotation of the region on the surface of the photoconductor drum 106 that comprises the latent electrostatic image. As the photoconductor drum 106 rotates, the toner adhered to the discharged areas of the drum contacts the recording medium 120, which has been charged by a transfer roller 128, such that the medium attracts the toner particles away from the surface of the photoconductor drum and onto the surface of the medium. Typically, the transfer of toner particles from the surface of the photoconductor drum 106 to the surface of the recording medium 120 is not completely efficient. Therefore, some toner particles remain on the surface of the photoconductor drum. As the photoconductor drum 106 continues to rotate, the toner particles that remain adhered to the drum's surface are removed by a cleaning blade 130 and deposited in a toner waste hopper 132.

As the recording medium 120 moves along the conveyance path past the photoconductor drum 106, a conveyer 134 delivers the recording medium to a fusing system 102. The recording media 120 passes between a fuser roller 136 and a pressure roller 138 of the fusing system 102. As the pressure roller 138 rotates, the fuser roller 136 is rotated and the recording medium 120 is pulled between the rollers. The heat applied to the recording medium 120 by the fusing system 102 fuses the toner to the surface of the recording medium. Finally, output rollers 140 draw the recording medium 120 out of the fusing system 102 and delivers it to an output tray 142.

As identified in FIG. 1, the device 100 can further include a formatter 144 and an imaging device controller 146. The formatter 144 acts as an image processor and therefore receives print data, such as a display list, vector graphics, or raster print data, from a print driver operating in conjunction with an application program of a separate host computing device 148. The formatter 144 converts the print data into a stream of binary print data and sends it to the controller 146. In addition, the formatter 144 and the controller 146 exchange data necessary for controlling the electrophotographic imaging process and the controller supplies the stream of binary print data to the laser scanner 108. The binary print data stream sent to the laser diode within the laser scanner 108 pulses the laser diode to create the latent electrostatic image on the photoconductor drum 106.

In addition to providing the binary print data stream to the laser scanner 108, the controller 146 controls a high voltage power supply (not shown) that supplies voltages and currents to the components used in the device 100 including the charge roller 104, the developing roller 112, and the transfer roller 128. The controller 146 further controls a drive motor (not shown) that drives the printer gear train (not shown) as well as the various clutches and feed rollers (not shown) necessary to move recording media 120 through the conveyance path of the device 100.

A power control circuit 150 controls the application of power to the fusing system 102. In one preferred arrangement, the power control circuit 150 is configured in the manner described in U.S. Pat. Nos. 5,789,723 and 6,018,151, which are hereby incorporated by reference into the present disclosure, such that the power to the fusing system 102 is linearly controlled and the power levels can be smoothly ramped up and down as needed. Such operation provides for better control over the amount of heat generated by the fusing system 102. While the device 100 is waiting to begin processing a print or copying job, the temperature of the fuser roller 136 is kept at a standby temperature corresponding to a standby mode.

In the standby mode, power is supplied at a reduced level to the fuser roller 136 by the power control circuit 150 to reduce power consumption, lower the temperature, and reduce the degradation resulting from continued exposure to the components of the fusing system 102 to the fusing temperatures. The standby temperature of the fuser roller 136 is selected to balance a reduction in component degradation against the time required to heat the fuser roller from the standby temperature to the fusing temperature. From the standby temperature, the fuser roller 136 can be quickly heated to the temperature necessary to fuse toner to the recording media 120. When processing of a fusing job begins, the controller 146, sufficiently ahead of the arrival of a recording medium 120 at the fusing system 102, increases the power supplied by the power control circuit 150 to the fusing system to bring its temperature up to the fusing temperature. After completion of the fusing job, the controller 146 sets the power control circuit 150 to reduce the power supplied to the fusing system 102 to a level corresponding to the standby mode. The cycling of the power supplied to fusing system 102 is ongoing during the operation of device as fusing jobs are received and processed and while the device is idle.

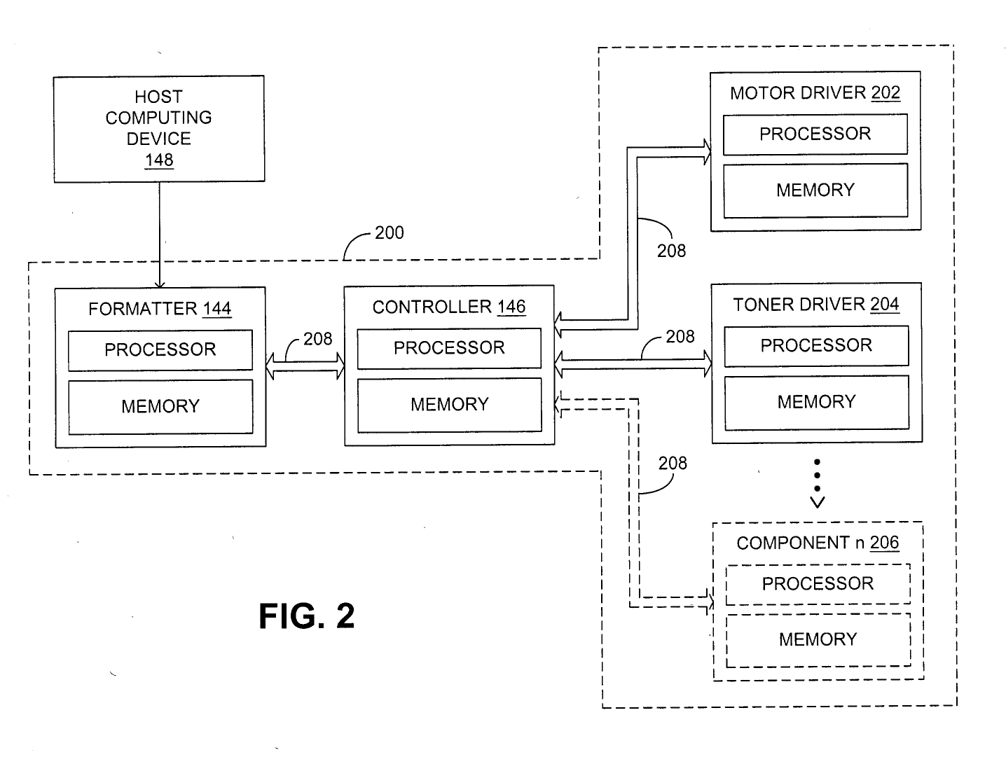

FIG. 2 illustrates a control/memory system 200 that can be used to control operation of the imaging device 100. As indicated in FIG. 2, the system 200 includes the formatter 144 and the imaging device controller 146 identified above, as well as other components not shown in FIG. 1. These other components can include, for example, a motor driver 202 (e.g., provided on a circuit board) that is used to drive and control some or all of the various imaging device motors, a toner driver 204 (e.g., provided on a circuit board) that is used to control toner concentration levels within the toner reservoir 116 as well as communicate with the memory elements contained on or within the various storage cartridges and developer cartridges in the case of a color imaging device. Furthermore, the system 200 can include various other components (identified generically by component “n” 206 in FIG. 2) that control various other aspects of imaging device operation. These other components may, for instance, comprise one or more “peripheral” devices (e.g., a duplexer, a book making device, etc.) that are used in conjunction with the imaging device.

As indicated in FIG. 2, each of the components of the control/memory system 200 can comprise a separate processor and memory. By way of example, each processor can comprise a general-purpose processor, a microprocessor, one or more application-specific integrated circuits (ASICs), a plurality of suitably configured digital logic gates, and other well known electrical configurations comprised of discrete elements both individually and in various combinations. Each memory can comprise any one of a combination of volatile memory elements (e.g., random access memory (RAM, such as DRAM, SRAM, etc.)) and nonvolatile memory elements (e.g., ROM, hard drive, tape, CDROM, etc.). Typically, the memory comprises one or more solid-state, nonvolatile memory elements. As is discussed below, the provision of memory to each of the various components permits redundant storage of data within the control/memory system 200. Preferably, each processor/memory pair is located on separate circuit boards, although persons having ordinary skill in the art will appreciate that alternative arrangements are feasible. Where the various memories are located on separate circuit boards, replacement of one board will typically not equate to removal of one or more other memories.

In the arrangement illustrated in FIG. 2, the controller 146 acts as a central point of control or “host” of the control/memory system 200 and is separately connected to the other components of the system with dedicated interfaces 208 (e.g., internal and/or external buses). Through these connections, any one component can interact with another of the system 200 using a given command protocol, at least via the controller 146. Although a centralized control arrangement is illustrated in FIG. 2 and has been described herein, it is to be understood that alternative arrangements may be used such as a shared bus arrangement, a cascade arrangement, and so forth.

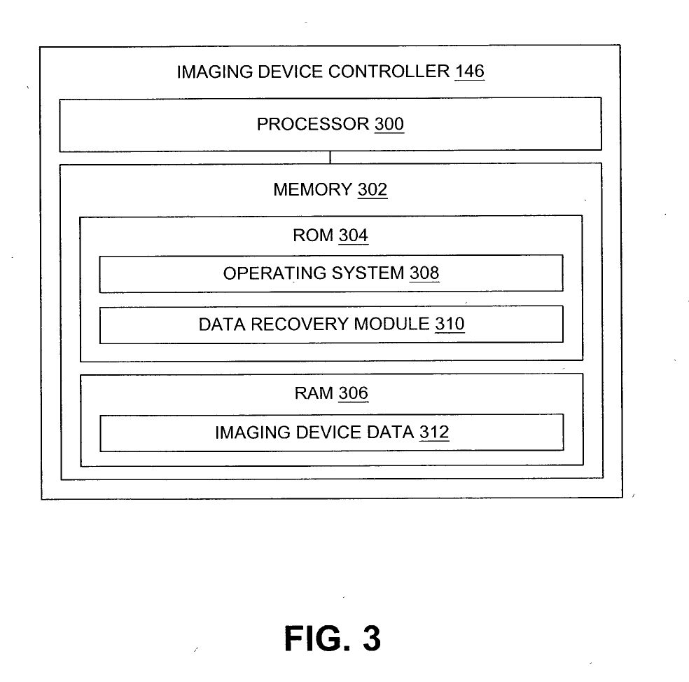

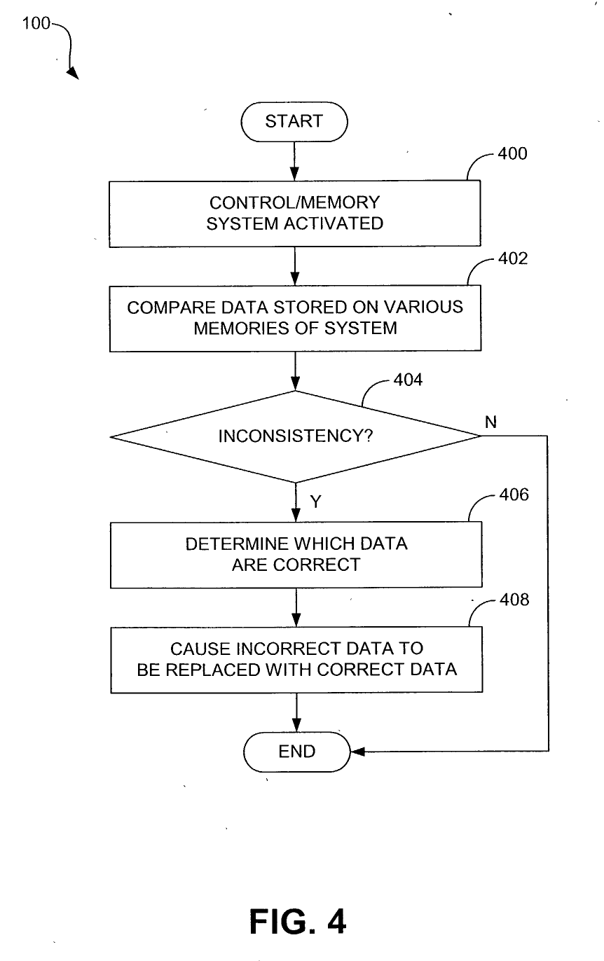

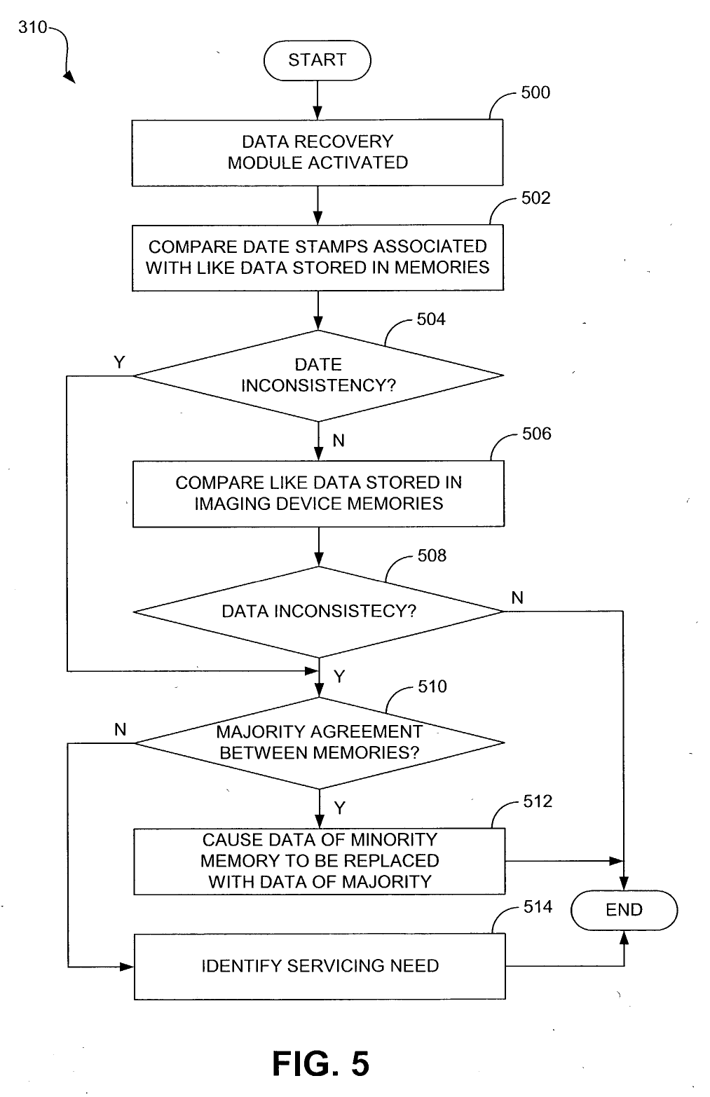

FIG. 3 illustrates an example configuration for the imaging device controller 146. As will be appreciated by persons having ordinary skill in the art, this example configuration is generally representative of the other components of the control/memory system 200 described above. As indicated in FIG. 3, the controller 146 includes a microprocessor 300 and memory 302. The memory 302 can comprise both read-only memory (ROM) 304 and random access memory (RAM) 306. The ROM 304 may store a basic operating system 308 that comprises the various commands that are executed by the microprocessor 300 to control operation of various imaging device components including the processors of other components within the control/memory system 200. In addition, the ROM 304 may store a data recovery module 310 that comprises various algorithms used to restore data that are lost or corrupted during device use or servicing. Examples of operation of the data recovery module 310 are discussed in relation to FIGS. 4 and 5 below.

As is further illustrated in FIG. 3, the RAM 306 may store imaging device data 312. The nature of these data will depend upon the application. By way of example, however, the data 312 may comprise production information specifically pertinent to the particular the imaging device (e.g., serial number, dates of manufacture, version numbers of software/firmware, etc.), machine constants (e.g., image alignment offsets), device use information (e.g., page counts, types of recording media used, types of toner used), and the like. Each of these types of information is normally contained in a predetermined location in memory. Furthermore, the various information is typically replicated on one or more other memories within the control/memory system 200 to provide for data restoration, as needed.

Various code (i.e., software and/or firmware) has been identified above. It is to be understood that this code can be stored on any computer-readable medium for use by or in connection with any computer-related system or method. In the context of this document, a computer-readable medium is an electronic, magnetic, optical, or other physical device or means that can contain or store code (e.g., in the form of a computer program) for use by or in connection with a computer-related system or method. The code can be embodied in any computer-readable medium for use by or in connection with an instruction execution system, apparatus, or device, such as a computer-based system, processor-containing system, or other system that can fetch the instructions from the instruction execution system, apparatus, or device and execute the instructions. The term “computer-readable medium” can be any means that can store, communicate, propagate, or transport the code for use by or in connection with the instruction execution system, apparatus, or device.

The computer-readable medium can be, for example but not limited to, an electronic, magnetic, optical, electromagnetic, infrared, or semiconductor system, apparatus, device, or propagation medium. More specific examples (a nonexhaustive list) of the computer-readable media include an electrical connection having one or more wires, a portable computer diskette, a random access memory (RAM), a read-only memory (ROM), an erasable programmable read-only memory (EPROM, EEPROM, or Flash memory), an optical fiber, and a portable compact disc read-only memory (CDROM). Note that the computer-readable medium can even be paper or another suitable medium upon which a program is printed, as the program can be electronically captured, via for instance optical scanning of the paper or other medium, then compiled, interpreted or otherwise processed in a suitable manner if necessary, and then stored in a computer memory.

As identified above, data are occasionally lost and/or corrupted during imaging device use or servicing. Such loss or corruption is undesirable in that it may interfere with proper device operation or data collection and review. To avoid these undesired consequences, the imaging device 100 is provided with multiple memories and data is stored on these memories in a redundant manner such that given data (e.g. machine constants) are stored on more than one memory. With such an arrangement, if data are lost or corrupted on one memory, it can be replaced with reference to another copy of the data residing on another memory.

An overview of the manner of operation identified above is provided in relation to the flow diagram of FIG. 4. It is to be understood that any process steps or blocks in flow diagrams of this document may represent modules, segments, or portions of code that include one or more executable instructions for implementing specific logical functions or steps in the process. It will be appreciated that, although particular example steps are described, alternative implementations are feasible. Moreover, steps may be executed out of order from that shown or discussed, including substantially concurrently or in reverse order, depending on the functionality involved.

Beginning with block 400 of FIG. 4, the control/memory system 200 is first activated. Such activation may occur, for instance, upon imaging device start-up or any other time (e.g., at the command of the user or service technician). Once activation has occurred, the data stored on the various memories of the system 200 are compared, as indicated in block 402. As noted above, this comparison is conducted so as to cross-reference like types of data stored in each respective memory of the system (or each memory designated to redundantly store these data).

At this point, it can be determined whether there are any inconsistencies between the data stored on the various different memories, as indicated in decision block 404. If not, presumably no loss or corruption of data has occurred and no data recovery is need. If, on the other hand, there are inconsistencies of one manner or another for data that should be identical due to redundant storage on the various memories, flow continues to block 406 at which it is determined by the system 200 which data are correct. After this determination is made, the system 200 causes the incorrect data to be replaced with the correct data, as indicated in block 408. In particular, the system causes the incorrect data of one or more memories to be overwritten by the correct data obtained from another memory.

Referring now to FIG. 5, an example of operation of the data recovery module 310 shown in FIG. 3 will be described. Although this module 310 is shown in FIG. 3 as being provided in memory 302 of the imaging device controller 146, persons having ordinary skill in the art will appreciate that this module can reside elsewhere, for instance in the memory of one or more other components of the control/memory system 200. Beginning with block 500 of FIG. 5, the data recovery module 310 is activated. Typically, such activation occurs at least every time that the imaging device is initialized (i.e., boots). In addition, activation of the module 310 can occur when the imaging device is reinitialized after “waking” from a standby or power-save mode of operation. Furthermore, activation of the module 310 can occur when required by the user or service technician.

Irrespective of the manner in which activation occurs, the data recovery module 310 next compares the date stamps associated with like data stored in the various memories of the control/memory system 200, as indicated in block 502. This is accomplished by reading the various memories directly or by commanding the local processors associated with each memory to read the date stamp and report back with its findings. As is known in the art, the date stamps are updated each time new data are stored and therefore indicates which memories may have an old (and therefore incorrect) version of the data in question. Once the date stamps have been compared, it can be determined whether there is a date inconsistency, as indicated in decision element 504. If so, flow continues down to decision block 510 described below. If there is not a date inconsistency, however, flow continues to block 506 at which the like data of the various memories are compared Through this comparison, it can be determined, as indicated in decision block 508, whether there is a data inconsistency. Such an inconsistency may indicate loss of data, corruption of data, or both. If there is no such inconsistency at block 508, all data is presumably correct and flow for the session is terminated.

If there is a data inconsistency, flow continues to decision element 510 at which it is determined whether a majority of memories agree as to which data are correct. Stated in other words, it is determined if a majority of the memories contain identical data for each respective type of data (e.g., machine constants, use information, etc.). Such majority agreement normally indicates that the memories in agreement contain the correct (i.e., complete and uncorrupted) data. If there is agreement between a majority of the memories, flow continues to block 512 and the data recovery module 310 causes the data of the memory or memories in the minority to be replaced with the data stored in the memories of the majority. By way of example, this can comprise sending a command to the processor of each component in the minority to rewrite the incorrect data with the correct data, which can be obtained from one or more memories of the majority. In this manner, data can be restored whether the wrong data was written to the minority memory or memories, or whether one or more imaging device components were replaced such that the original memory associated with the component(s) has been removed (i.e., lost) from the imaging device. Notably, such data restoration can occur in this manner even when it is the imaging device controller 146 that has been replaced in that the data recovery module 310 is configured to arbitrate according to majority rule regardless of which memory is in the minority.

If there is no majority agreement in block 510, flow continues down to block 514 at which a service need is identified to the user. By way of example, an error message or other indication can be displayed in a display screen of the device control panel to alert the user as to the need to determine the reason for the discrepancies. Although this may require a service call, such situations will arise infrequently, far less frequently than if redundant data storage were not practiced.

While particular embodiments of the invention have been disclosed in detail in the foregoing description and drawings for purposes of example, it will be understood by those skilled in the art that variations and modifications thereof can be made without departing from the scope of the invention as set forth in the following claims.

What is claimed is:

1. A control/memory system for an imaging device, comprising:
at least two separate components each including its own processor and memory; and
a data recovery module configured to restore data to memory within the control/memory system in the event such data are lost or corrupted.

2. The system of claim 1, wherein the at least two components comprise a formatter and an imaging device controller.

3. The system of claim 2, wherein the data recovery module is stored within memory of the imaging device controller.

4. The system of claim 2, wherein the at least two components further comprise a motor driver and a toner driver.

5. The system of claim 1, wherein the data recovery module is configured to determine whether there is an inconsistency between data stored on one memory as compared to data stored on another memory within the system.

6. The system of claim 5, wherein the data recovery module is further configured to cause incorrect data to be replaced with correct data if it is determined that there is an inconsistency.

7. The system of claim 6, wherein the data recovery module determines that the data stored by a majority of the memories of the system is the correct data.

8. The system of claim 1, wherein the data include information pertaining to at least one of imaging device production, machine constants, and imaging device use information.

9. An imaging device, comprising:
a print engine including a charge roller, a photoconductor drum, a laser scanner, and a developing roller; and
a control/memory system including at least two separate components each including its own processor and memory, and a data recovery module configured to restore data to memory within the control/memory system in the event such data are lost or corrupted.

10. The device of claim 9, wherein the at least two components of the control/memory system comprise a formatter and an imaging device controller.

11. The device of claim 10, wherein the data recovery module is stored within memory of the imaging device controller.

12. The device of claim 9, wherein the data recovery module is configured to determine whether there is an inconsistency between data stored on one memory as compared to data stored on another memory within the control/memory system.

13. The device of claim 12, wherein the data recovery module is further configured to cause incorrect data to be replaced with correct data if it is determined that there is an inconsistency.

14. The device of claim 13, wherein the data recovery module determines that the data stored by a majority of the memories of the control/memory system is the correct data.

15. The device of claim 9, wherein the data include information pertaining to at least one of imaging device production, machine constants, and imaging device use information.

16. A method for recovering data within an imaging device, comprising:
comparing data stored on various different memories of the imaging device;
determining if there is an inconsistency between the data of the various different imaging device memories;
determining which data are correct and which data are incorrect if there is an inconsistency; and
causing the incorrect data to be replaced with the correct data.

17. The method of claim 16, wherein the step of determining which data are correct and which data are incorrect comprises determining if there is agreement as to the data between a majority of the imaging device memories that store the data.

18. The method of claim 17, wherein the step of determining which data are correct and which data are incorrect further comprises designating data stored by the majority of imaging device memories as correct.

19. The method of claim 17, wherein the step of causing the incorrect data to be replaced with the correct data comprises causing a processor associated with the memory comprising the incorrect data to write the correct data over the incorrect data.

20. A data recovery module stored on a computer-readable medium, comprising:
logic configured to compare data stored on various different memories of the imaging device;
logic configured to determine if there is an inconsistency between the data of the various different imaging device memories;
logic configured to determine which data are correct and which data are incorrect if there is an inconsistency; and
logic configured to cause the incorrect data to be replaced with the correct data.

21. The module of claim 20, wherein the logic configured to determine which data are correct and which data are incorrect comprises logic configured to determining if there is agreement as to the data between a majority of the imaging device memories that store the data.

22. The module of claim 21, wherein the logic configured to determine which data are correct and which data are incorrect further comprises logic configured to designate data stored by the majority of imaging device memories as correct.

23. The module of claim 21, wherein the logic configured to cause the incorrect data to be replaced with the correct data comprises logic configured to cause a processor associated with the memory comprising the incorrect data to write the correct data over the incorrect data.
